(19) United States
(12) Patent Application Publication
(10) Pub. No.: US 2007/0200119 A1
(43) Pub. Date: Aug. 30, 2007

(54) FLIP-CHIP LED PACKAGE AND LED CHIP

(76) Inventors: Yun-Li Li, Tao-Yung Hsien (TW); Way-Jze Wen, Tao-Yung Hsien (TW); Fen-Ren Chien, Tao-Yung Hsien (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/307,875

(22) Filed: Feb. 26, 2006

(51) Int. Cl. H01L 33/00

(52) U.S. Cl. 257/79

(57) ABSTRACT

A light emitting diode (LED) chip mainly includes a substrate, a first type doped semiconductor layer, light-emitting layers, second type doped semiconductor layers, a first electrode and second electrodes. The first type doped semiconductor layer is disposed on the substrate and includes protrusions which is upward extended; the light-emitting layers are disposed on the corresponding protrusions respectively; the second type doped semiconductor layers are disposed on the corresponding light-emitting layers respectively; the first electrode is disposed on the first type doped semiconductor layer except the protrusions and electrically connected to the first type doped semiconductor layer; the second electrodes are disposed on the corresponding second type doped semiconductor layers respectively; and the first electrode is electrically insulated from the second electrodes.

### BACKGROUND OF THE INVENTION

1. Field of Invention

The present invention relates to a light emitting diode (LED) package and an LED chip, and particularly to a flip-chip LED package with good luminous efficiency and an LED chip.

2. Description of the Related Art

Over the years, LED devices with a cluster of varied GaN (gallium nitride) compounds, such as GaN (gallium nitride), AlGaN (aluminum gallium nitride), InGaN (indium gallium nitride), have gained astonishing prosperity in semiconductor industry. The above-mentioned three types of nitrides belong to a wideband gap semiconductor material family, which has light-wavelengths ranging from ultraviolet to red light, almost covering entire visual light waveband. In comparison to conventional bulbs, LEDs take overwhelming superiority, such as mini size, longer lifetime, low driving voltage/current, crack-resistant, mercury-free (no pollution issue) and good luminous efficiency (electricity-saving). With these advantages, LEDs are widely applied.

FIG. 1A is a schematic top view of a conventional LED and FIG. 1B is a schematic cross-sectional view along line l-l′ in FIG. 1A. Referring to FIGS. 1A and 1B, a conventional LED 100 includes a substrate 110, a first type doped and patterned semiconductor layer 122, a light-emitting layer 124 and a second type doped semiconductor layer 126. The substrate 110 can be an aluminum oxide (AlO) substrate. The first type doped and patterned semiconductor layer 122 is disposed on the substrate 110, and the second type doped semiconductor layer 126 is disposed on the protruding area of the light-emitting layer 124. It should be noted that the above-mentioned first type doped semiconductor layer 122 and second type doped semiconductor layer 126 must be different type of doped semiconductor layers. For example, if the first type doped semiconductor layer 122 is a P-type doped semiconductor layer, the second type doped semiconductor layer 126 must be an N-type doped semiconductor layer.

In more detail, on the second type doped semiconductor layer 126 and the portion of the first type doped semiconductor layer 122 uncovered by the second type doped semiconductor layer 126, a pad 132 and a pad 134 are usually disposed, respectively. The pads 132 and 134 are usually made of metal. According to the prior art, a conventional LED is electrically connected to a circuit board or other carrier in wire-bonding mode or flip-chip mode, wherein the pads 132 and 134 serve as a medium for connecting the LED 100 to the circuit board or other carrier.

However, the pads 132 and 134 in the above-described LED 100 are located at two opposite corners of the substrate 110; and most of the current takes a shortest path P to travel. Therefore, the current is unevenly distributed, which makes the area A of the LED 100 have better luminous efficiency but a poor luminous efficiency at other areas. As a result, the overall luminous efficiency performance of the LED 100 is degraded.

Therefore, how to improve the disposition of the pads in an LED to increase the overall luminous efficiency of an LED is an issue to be solved.

### SUMMARY OF THE INVENTION

An object of the present invention is to provide an LED chip with better luminous efficiency.

Another object of the present invention is to provide a flip-chip LED package, wherein the current distribution of the LED chip is modified for improving the luminous efficiency thereof.

To achieve the above-described objects or others, the present invention provides an LED chip, which mainly includes a substrate, a first type doped semiconductor layer, a plurality of light-emitting layers, a plurality of second type doped semiconductor layers, a first electrode and a plurality of second electrodes. The first type doped semiconductor layer is disposed on the substrate and includes a plurality of upward-extended protrusions. The plurality of light-emitting layers is disposed on the corresponding protrusions, respectively. The plurality of the second type doped semiconductor layers is disposed on the corresponding light-emitting layers, respectively. The first electrode is disposed on the first type doped semiconductor layer except the above-described protrusions and electrically connected to the first type doped semiconductor layer. While the plurality of second electrodes is disposed on the corresponding second type doped semiconductor layers and electrically connected to the same, wherein the first electrode is electrically insulated from the second electrodes.

To achieve the above-described objects or others, the present invention further provides a flip-chip LED package, which mainly includes a sub-base and the above-described LED chip. The sub-base includes a first conductive pattern and a second conductive pattern and both of the patterns are electrically insulated from each other. The first electrode of the LED chip corresponds to the first conductive pattern of the sub-base. In addition, the second electrode of the LED chip corresponds to the second conductive pattern of the sub-base and both the electrodes are electrically connected to each other.

In an embodiment of the present invention, the first type doped semiconductor layer is an N-type semiconductor layer, while the second type doped semiconductor layer is a P-type one.

In an embodiment of the present invention, the first type doped semiconductor layer includes a buffer layer, a first contact layer and a plurality of first bonding layers. The buffer layer is disposed on the substrate; the first contact layer is disposed on the buffer layer and includes up-extended protrusions. The plurality of first bonding layers is disposed on the corresponding protrusions.

In an embodiment of the present invention, each of the second type doped semiconductor layers includes a second bonding layer and a second contact layer. Each of the second bonding layers is disposed on the corresponding light-emitting layer and the second bonding layer is disposed on the second bonding layer.

In an embodiment of the present invention, the shape of above-described protrusion is polygon. In addition, the shape of each protrusion can be circle or ellipse as well.

In an embodiment of the present invention, the LED chip further includes an insulation layer disposed on a portion of the first type doped semiconductor layer and portions of the second type doped semiconductor layers for electrically insulating the second electrodes from the first electrode.

In an embodiment of the present invention, the flip-chip LED package further includes a plurality of conductive bumps, which are disposed between the first electrode and the first conductive pattern and between the second electrodes and the second conductive pattern as well.

In an embodiment of the present invention, the first conductive pattern includes a plurality of pads, which are electrically connected to the first electrode and the pads are electrically connected to each other through a conductive trace inside the sub-base.

In an embodiment of the present invention, the first conductive pattern includes a patterned conductive trace.

In an embodiment of the present invention, the patterned conductive trace includes a ring-shape conductive trace, a U-shape conductive trace, a C-shape conductive trace, a plurality of bar-shape conductive traces or a plurality of L-shape conductive traces.

In an embodiment of the present invention, the second conductive pattern includes a plurality of pads, which are electrically connected to the second electrode and the pads are electrically connected to each other through a conductive trace inside the sub-base.

In an embodiment of the present invention, the second conductive pattern includes a patterned conductive trace.

In an embodiment of the present invention, the patterned conductive trace includes a ring-shape conductive trace, a U-shape conductive trace, a C-shape conductive trace, a plurality of bar-shape conductive traces or a plurality of L-shape conductive traces.

In summary, in the LED chip and the flip-chip LED package of the present invention, by means of changing the shapes and the disposition manner of the first electrode and the second electrodes, the first electrode is able to be disposed on a peripheral area around the second electrodes. Thus, the current drawn into the LED chip is in radiant distribution and the most parts of the light-emitting layers are capable of emitting light effectively, which improves the overall luminous efficiency of the LED chip.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve for explaining the principles of the invention.

FIG. 1A is a schematic top view of a conventional LED.

FIG. 1B is a schematic cross-sectional view along line l-l′ in FIG. 1A.

FIG. 2A is a schematic 3-D explosive view of an LED chip of the present invention.

FIG. 2B is a schematic top view of the LED chip after assembling all the parts in FIG. 2A.

FIG. 2C is a schematic cross-sectional view along line ll-ll′ in FIG. 2B.

FIG. 3 is a localized cross-sectional view showing a first type doped semiconductor layer, a light-emitting layer and a second type doped semiconductor layer in an LED chip of the present invention.

FIG. 4 is a schematic 3-D explosive view showing a flip-chip LED package of the present invention.

FIG. 5A˜5D are schematic 3-D explosive views of the sub-bases having different kinds of patterned conductive traces of the present invention.

### DESCRIPTION OF THE EMBODIMENTS

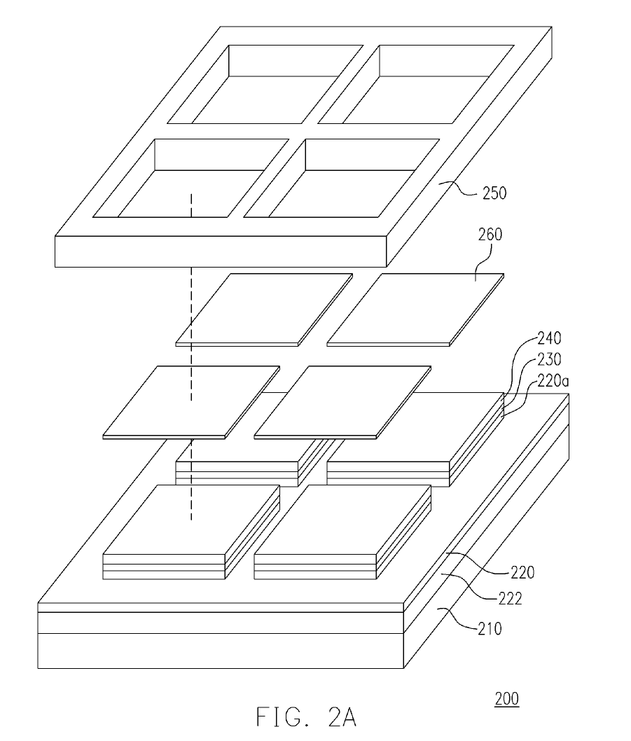

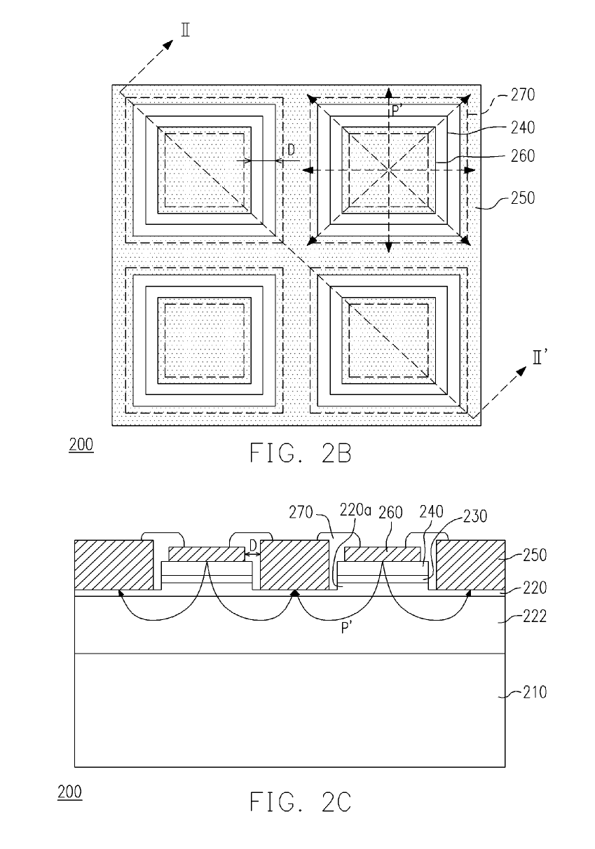

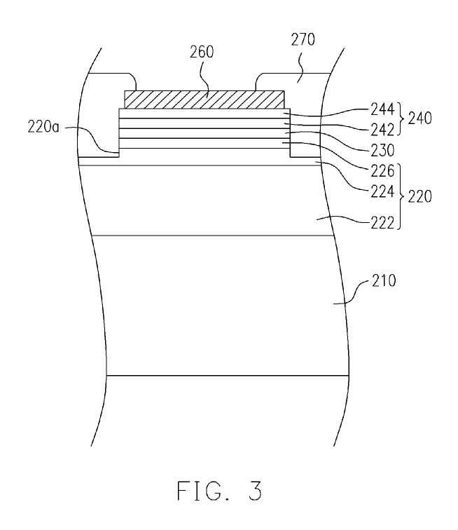

FIG. 2A is a schematic 3-D explosive view of an LED chip of the present invention, FIG. 2B is a schematic top view of the LED chip after assembling all the parts in FIG. 2A and FIG. 2C is a schematic cross-sectional view along line ll-ll′ in FIG. 2B. Referring to FIGS. 2A, 2B and 2C, the LED chip 200 of the present invention mainly includes a substrate 210, a first type doped semiconductor layer 220, a plurality of light-emitting layers 230, a plurality of second type doped semiconductor layers 240, a first electrode 250 and a plurality of second electrodes 260. The first type doped semiconductor layer 220 is disposed on the substrate 210 including a plurality of up-extended protrusions 220a separated from each other; the plurality of light-emitting layers 230 is disposed on the corresponding protrusions 220a, respectively; the plurality of the second type doped semiconductor layers 240 is disposed on the corresponding light-emitting layers 230, respectively; the first electrode 250 is disposed on the portion of the first type doped semiconductor layer 220 that is not in the protrusions 220a and electrically connected to the first type doped semiconductor layer 220; while the plurality of second electrodes 260 is disposed on the corresponding second type doped semiconductor layers 240 and electrically connected to the second type doped semiconductor layers 240. In addition, the first electrode 250 is electrically insulated from the second electrodes 260.

The material of the substrate 210 is a semiconductor material or a non-semiconductor material, for example, silicon, glass, gallium arsenide (GaAs), gallium nitride (GaN), aluminum gallium arsenide (AlGaAs), gallium phosphide (GaP), silicon carbide (SiC), indium phosphide (lnP), boron nitide (BN), aluminum oxide (AlO) or aluminum nitride (AlN). On the substrate 210, a buffer layer 222 can be selectively formed. The first type doped semiconductor layer 220 is disposed on the substrate 210 and includes a plurality of up-extended protrusions 220a which is separate from each other. In an embodiment of the present invention, the first type doped semiconductor layer 220 can be, for example, an N-type semiconductor layer. The protrusions 220a thereof can be rectangular and all the protrusions 220a are arranged in a matrix mode. However, the number, shape and arrangement can be modified depending on different application. The shape of a protrusion can be circle, ellipse, polygon and so on. The present invention does not limit the number, shape and arrangement of the protrusions 220a.

A plurality of light-emitting layers 230 is disposed on the corresponding protrusions 220a, respectively. Therefore, the shape of the light-emitting layers must match the protrusions 220a. In an embodiment, the light-emitting layers 230 can be, for example, a multiple quantum well (MQW) made of GaN/lnGaN. A plurality of the second type doped semiconductor layers 240 is disposed on the corresponding light-emitting layers 230, respectively, and the shape thereof must match the light-emitting layers 230. In an embodiment of the present invention, the second type doped semiconductor layers 240 can be, for example, a P-type semiconductor layer.

FIG. 3 is a localized cross-sectional view showing a first type doped semiconductor layer, a light-emitting layer and a second type doped semiconductor layer in an LED chip of the present invention. Referring to FIG. 3, in an embodiment, the first type doped semiconductor layer 220 includes, for example, the above-described buffer layer 222, a first contact layer 224 and a plurality of first bonding layers 226. In FIG. 3, only one of the first bonding layers 226 is shown as exemplary. The buffer layer 222 is disposed on the substrate 210. The first contact layer 224 is disposed on the buffer layer 222 and includes a plurality of up-extended protrusions 220a. The first bonding layers 226 are disposed on the corresponding protrusions 220a and made of N-type doped gallium nitride (GaN). The light-emitting layers 230 are disposed on the first bonding layers 226. Each of the second type doped semiconductor layers 240 includes a second bonding layer 242 and a second contact layer 244. The second bonding layer 242 is disposed on the light-emitting layer 230 and made of P-type doped gallium nitride (GaN). The second contact layer 244 is disposed on the second bonding layer 242 and made of P-type doped gallium nitride (GaN).

Please continue to refer to FIGS. 2A˜2C, the first electrode 250 is disposed on the portion of the first type doped semiconductor layer 220 that is not in the protrusions 220a and electrically connected to the first type doped semiconductor layer 220. In an embodiment, the protrusions 220a are surrounded by the first electrode 250, and there is a gap D between the first electrode 250 and the protrusions 220a. The material of the first electrode 250 can be, for example, aluminum-titanium alloy. The plurality of the second electrodes 260 are disposed on the corresponding second type doped semiconductor layers 240, respectively, and electrically connected to the second type doped semiconductor layers 240. Therefore, the shape of the second electrodes 260 must match the second type doped semiconductor layers 240 and the first electrode 250 is electrically insulated from the second electrodes 260. The material of the second electrodes 260 includes N-type transparent conductive oxide layer (TCO layer) and P-type transparent conductive oxide layer (TCO layer). The material of the N-type TCO layer is indium tin oxide (lTO), while the material of the P-type TCO layer is conductive oxides of delafossite (CuAlO2) and so on.

The insulation layer 270 (as shown in FIG. 2C) is optionally disposed on the portion of the first type doped semiconductor layer 220 and the portion of the second type doped semiconductor layer 240 to guarantee the insulation between the first electrode 250 and the second electrode 260. In an embodiment of the present invention, the insulation layer 270 is made of, for example, an insulation material.

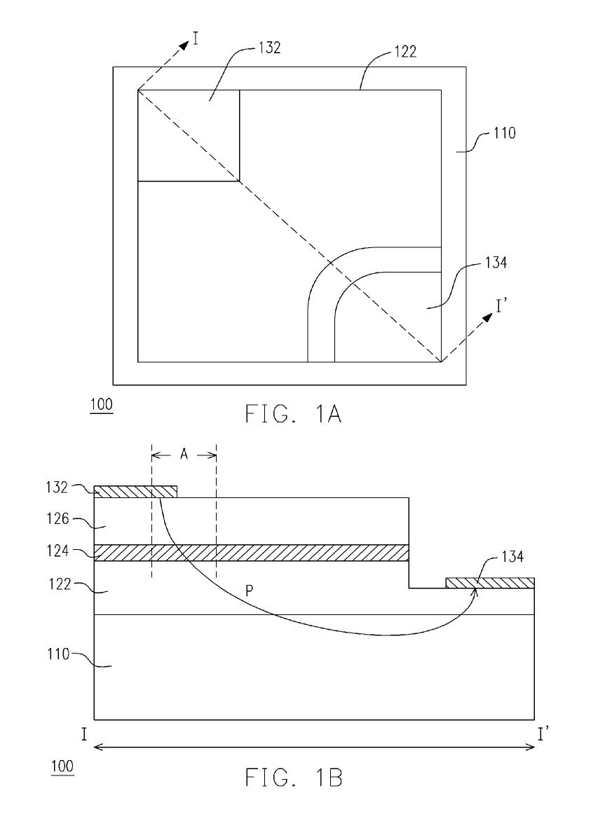

Since the first electrode 250 is disposed on a peripheral area of the second electrodes 260, therefore, it is distinguished from the prior art (as shown in FIG. 1B) that as the current exerted to the LED chip 200 draws into the light-emitting layer 230 from the second electrode 260, the current takes a radiant distribution (current path P′ as shown in FIGS. 2B and 2C). Such a better current distribution contributes to enable the most part of the light-emitting layer 230 to work efficiently and accordingly to improve the overall luminous efficiency of the LED chip 200.

The dispositions of the first electrode 250 and the second electrode 260 in the present invention are very different from the electrode (or the pads) dispositions in a conventional LED chip. To adapt the unique feature and the above-described LED chip, the present invention further provides a novel flip-chip LED package structure.

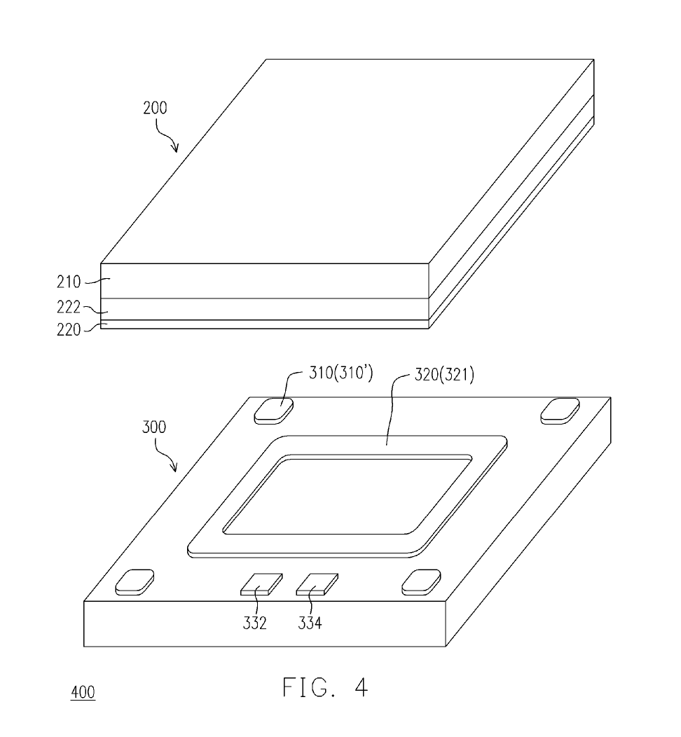

FIG. 4 is a schematic 3-D explosive view of a flip-chip LED package of the present invention. Referring to FIG. 4, a flip-chip LED package 400 includes an LED chip 200 and a sub-base 300. The LED chip 200 is disposed on the sub-base 300. The related structure of the LED chip 200 is described hereinabove and for simplicity, it is omitted herein. On the sub-base 300, a first conductive pattern 310 and a second conductive pattern 320 are made. The first conductive pattern 310 and the second conductive pattern 320 are made of conductive material, for example, gold, copper or nickel and the two kinds of patterns are electrically insulated from each other. Referring to FIG. 2C and FIG. 4, the first electrode 250 of the LED chip 200 corresponds to and electrically connects with the first conductive pattern 310 of the sub-base 300. Therefore, the designed pattern of the first conductive pattern 310 must match the first electrode 250 to guarantee the current is able to be transmitted to the first electrode 250 via the first conductive pattern 310. Similarly, the second electrode 260 of the LED chip 200 corresponds to and electrically connects with the second conductive pattern 320 of the sub-base 300.

In addition, the flip-chip LED package 400 further includes a plurality of conductive bumps (not shown in the figure) disposed between the first electrode 250 and the first conductive pattern 310 and between the second electrode 260 and the second conductive pattern 320. The conductive bumps serve as media for electrically connecting between the LED chip 200 and the sub-base 300.

In the embodiment, an N-type pad 332 and a P-type pad 334 are further disposed on the sub-base 300. The N-type pad 332 is coupled to a voltage source, while the P-type pad 334 is coupled to another voltage source. By means of a voltage level difference between the N-type pad 332 and the P-type pad 334, a current is generated for driving the LED chip 200.

As shown in FIG. 4, the first conductive pattern 310 includes, for example, a plurality of pads 310′, which are coupled to the N-type pad 332 through a surface conductive trace or an internal conductive trace of the sub-base 300 and coupled to the same voltage source. Furthermore, the pad 310′ is electrically connected to the first electrode 250 of the LED chip 200. The second conductive pattern 320 can be, for example, a patterned conductive trace, such as a ring-shape conductive trace 321 shown in FIG. 4. Similarly, the ring-shape conductive trace 321 is coupled to the P-type pad 334 through a surface conductive trace or an internal conductive trace of the sub-base 300.

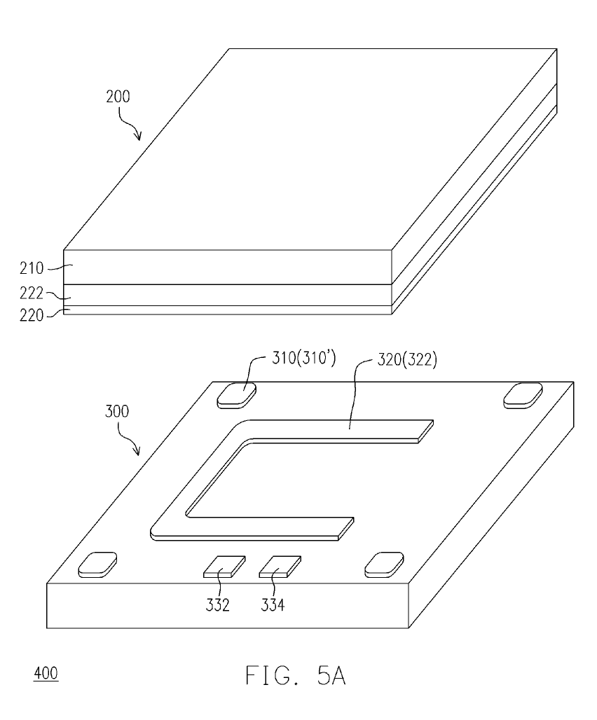

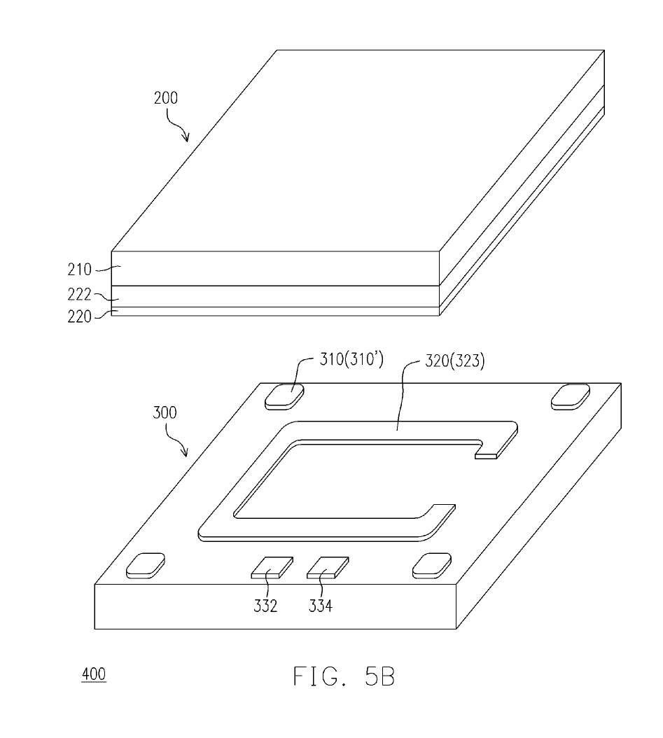

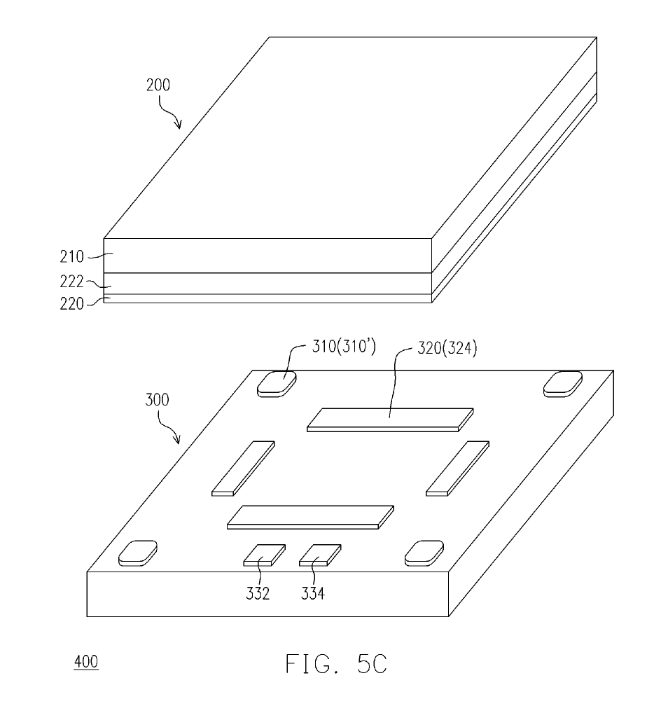

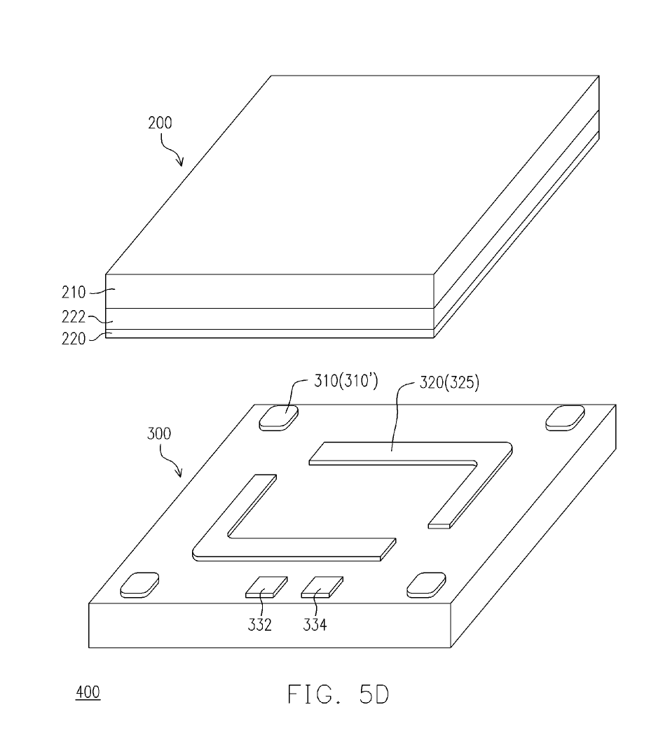

FIG. 5A˜5D are schematic 3-D explosive views of the sub-bases having different kinds of patterned conductive traces of the present invention. Referring to FIGS. 5A and 5B, the patterned conductive traces in the above-described sub-base 300 can be a U-shape conductive trace 322 in FIG. 5A or a C-shape conductive trace 323 in FIG. 5B. Continuously referring to FIGS. 5C and 5D, the patterned conductive traces herein can be a plurality of bar-shape conductive trace 324 in FIG. 5C or a plurality of L-shape conductive trace 325 in FIG. 5D. The bar-shape conductive traces 324 and the L-shape conductive traces 325 are coupled to the P-type pad 334 through a surface conductive trace or an internal conductive trace of the sub-base 300 and coupled to the same voltage source. In another embodiment of the present invention, the first conductive pattern 310 can be one of the above-described patterned conductive traces, while the second conductive pattern 320 can include, for example, a plurality of pads. The present invention does not limit the first conductive pattern 310 and the second conductive pattern 320 to the above-described shapes of the conductive traces. Any type of the conductive traces capable of connecting the first conductive pattern 310 and the second conductive pattern 320 to the first electrode 250 and the second electrode 260, respectively, is allowed to be employed.

In summary, in the LED chip and the flip-chip LED package of the present invention, by means of changing the shapes and the disposition manner of the first electrode and the second electrodes, the first electrode is able to be disposed on a peripheral area around the second electrodes. Thus, the current drawn into the LED chip is in radiant distribution and the most parts of the light-emitting layers are capable of effectively emitting light, which definitely improves the overall luminous efficiency.

It will be apparent to those skilled in the art that various modifications and variations can be made to the structure of the present invention without departing from the scope or spirit of the invention. In view of the foregoing, it is intended that the specification and examples to be considered as exemplary only, with a true scope and spirit of the invention being indicated by the following claims and their equivalents.

What is claimed is:

1. An LED chip, comprising:
a substrate;
a first type doped semiconductor layer, disposed on the substrate and comprising a plurality of up-extended protrusions;
a plurality of light-emitting layers, disposed on the corresponding protrusions, respectively;
a plurality of second type doped semiconductor layers, disposed on the light-emitting layers, respectively;
a first electrode, disposed on the first type doped semiconductor layer except the protrusions and electrically connected to the first type doped semiconductor layer; and
a plurality of second electrodes, disposed on the corresponding second type doped semiconductor layers and electrically connected to the second type doped semiconductor layers, wherein the first electrode is electrically insulated from the second electrodes.

2. The LED chip as recited in claim 1, wherein the first type doped semiconductor layer is an N-type semiconductor layer, while the second type doped semiconductor layer is a P-type semiconductor layer.

3. The LED chip as recited in claim 1, wherein the first type doped semiconductor layer comprises:
a buffer layer, residing on the substrate;
a first contact layer, residing on the buffer layer and comprising the up-extended protrusions; and
a plurality of first bonding layers, disposed on the corresponding protrusions, respectively.

4. The LED chip as recited in claim 1, wherein the second type doped semiconductor layer comprises:
a second bonding layer; and
a second contact layer, wherein the second bonding layer is disposed on the corresponding light-emitting layer and the second contact layer is disposed on the second bonding layer.

5. The LED chip as recited in claim 1, wherein the shape of each protrusion is polygon.

6. The LED chip as recited in claim 1, wherein each of the protrusions is circle-like or ellipse-like.

7. The LED chip as recited in claim 1, further comprising an insulation layer disposed on a portion of the first type doped semiconductor layer and a portion of the second type doped semiconductor layer for electrically insulating the first electrode from the second electrodes.

8. A flip-chip LED package, comprising:
a sub-base, comprising a first conductive pattern and a second conductive pattern, wherein the first conductive pattern is electrically insulated from the second conductive pattern;
an LED chip, disposed on the sub-base and comprising:
a substrate;
a first type doped semiconductor layer, residing on the substrate and comprising a plurality of up-extended protrusions;
a plurality of light-emitting layers, disposed on the corresponding protrusions, respectively;
a plurality of second type doped semiconductor layers, disposed on the light-emitting layers, respectively;
a first electrode, disposed on the first type doped semiconductor layer except the protrusions and corresponding to the first conductive pattern, wherein the first electrode is electrically connected to the first type doped semiconductor layer and the first conductive pattern; and
a plurality of second electrodes, disposed on the corresponding second type doped semiconductor layers and corresponding to the second conductive pattern, wherein the second electrodes are electrically connected to the second type doped semiconductor layers and the second conductive pattern.

9. The flip-chip LED package as recited in claim 8, further comprising a plurality of conductive bumps disposed between the first electrode and the first conductive pattern and between the second electrode and the second conductive pattern, respectively.

10. The flip-chip LED package as recited in claim 8, wherein the first conductive pattern comprises a plurality of pads, the pads are electrically connected to the first electrode and the pads are electrically connected to each other via the conductive trace inside the sub-base.

11. The flip-chip LED package as recited in claim 8, wherein the first conductive pattern comprises a patterned conductive trace.

12. The flip-chip LED package as recited in claim 11, wherein the patterned conductive trace comprises a ring-shape conductive trace, a U-shape conductive trace, a C-shape conductive trace, a plurality of bar-shape conductive traces and a plurality of L-shape conductive traces.

13. The flip-chip LED package as recited in claim 8, wherein the second conductive pattern comprises a plurality of pads, the pads are electrically connected to the second electrode and the pads are electrically connected to each other via the conductive trace inside the sub-base.

14. The flip-chip LED package as recited in claim 8, wherein the second conductive pattern comprises a patterned conductive trace.

15. The flip-chip LED package as recited in claim 14, wherein the patterned conductive trace comprises a ring-shape conductive trace, a U-shape conductive trace, a C-shape conductive trace, a plurality of bar-shape conductive traces and a plurality of L-shape conductive traces.

16. The flip-chip LED package as recited in claim 14, wherein the first type doped semiconductor layer is an N-type semiconductor layer, while the second type doped semiconductor layer is a P-type semiconductor layer.

17. The flip-chip LED package as recited in claim 8, wherein the first type doped semiconductor layer comprises:
a buffer layer, residing on the substrate;
a first contact layer, residing on the buffer layer and comprising the up-extended protrusions; and
a plurality of first bonding layers, disposed on the corresponding protrusions, respectively.

18. The flip-chip LED package as recited in claim 8, wherein the second type doped semiconductor layer comprises:
a second bonding layer; and
a second contact layer, wherein the second bonding layer is disposed on the corresponding light-emitting layer and the second contact layer is disposed on the second bonding layer.

19. The flip-chip LED package as recited in claim 8, wherein the shape of each protrusion is polygon.

20. The flip-chip LED package as recited in claim 8, wherein the shape of each protrusion is circle or ellipse.

21. The flip-chip LED package as recited in claim 8, further comprising an insulation layer disposed on a portion of the first type doped semiconductor layer and a portion of the second type doped semiconductor layer for electrically insulating the first electrode from the second electrodes.
